(19) United States
(12) Patent Application Publication
(10) Pub. No.: US 2020/0185188 A1
(43) Pub. Date: Jun. 11, 2020

(54) MECHANICAL FEEDTHROUGH APPARATUS

(71) Applicant: METAL INDUSTRIES RESEARCH & DEVELOPMENT CENTRE, Kaohsiung City (TW)

(72) Inventors: Jyh-Nan Shieh, Tainan City (TW); Kuny-Ming Hsu, Kaohsiung City (TW); Ching-Fu Yang, Kaohsiung City (TW); Mei-Jung Ho, Kaohsiung City (TW); Ting-Pin Cho, Kaohsiung City (TW)

(21) Appl. No.: 16/211,377

(22) Filed: Dec. 6, 2018

(51) Int. Cl. H01J 37/18; H01J 37/34; H01J 37/32

(52) U.S. Cl. CPC H01J 37/185; H01J 37/32724; H01J 37/3488

(57) ABSTRACT

A mechanical feedthrough apparatus is provided to be mounted on a pivot base of a vacuum apparatus. A first axial tube of the mechanical feedthrough apparatus is pivotally connected to the pivot base and a second axial tube of the mechanical feedthrough apparatus is inserted into the first axial tube. An external cone surface of the second axial tube contacts with an internal cone surface of a first axial tube such that the second axial tube is close-fitted to the first axial tube.

### FIELD OF THE INVENTION

This invention generally relates to a mechanical feedthrough apparatus, and more particularly to a mechanical feedthrough apparatus which is designed to be mounted on a vacuum apparatus.

### BACKGROUND OF THE INVENTION

Vacuum is required for the conventional sputtering process and a stage placed in a sputtering chamber has to be preheated before sputtering. Granted Taiwan patent No. 1521153 (application No. 103135707) discloses a mechanical vacuum feedthrough apparatus with linear movement, an inner bush 30 is disposed in a base 10, a shaft 40 is inserted in the inner bush 30 and a sealing ring 50 is placed between the inner bush 30 and the shaft 40 to seal the gap between the inner bush 30 and the shaft 40.

However, because of long-term high temperature, ageing or distortion of the sealing ring 50 may be occurred easily to cause the leakage between the inner bush 30 and the shaft 40.

### SUMMARY

One object of the present invention is to improve the air-tightness between first and second axial tubes by attaching an internal cone surface of the first axial tube to an external cone surface of the second axial tube closely.

Another object of the present invention is to allow the first axial tube to axially expand with the second axial tube by an expansion segment of the first axial tube so as to prevent the expansion of the second axial tube from reducing the air-tightness between the first and second axial tubes.

A mechanical feedthrough apparatus of the present invention provided to be mounted on a pivot base of a vacuum apparatus includes a first axial tube and a second axial tube. The first axial tube includes a pivot segment and a joint segment. The pivot segment is pivotally connected to a pivot opening of the pivot base and has a first joint opening, the joint segment has a second joint opening communicating with the first joint opening, and there is an internal cone surface in the second joint opening. The second axial tube includes a first joint segment and a second joint segment. The first joint segment is inserted in the first joint opening and the second joint segment is inserted in the second joint opening. There is an external cone surface on the second joint segment and the second axial tube contacts with the internal cone surface via the external cone surface.

For enlarging the contact area of the first and second axial tubes, the external cone surface of the second axial tube is designed to contact the internal cone surface of the first axial tube in the present invention. Furthermore, the heated fluid delivered to the second axial tube can expand the second axial tube and allow the external cone surface to attach with the internal cone surface closely so that the air-tightness between the first and second axial tubes is improved.

### DESCRIPTION OF THE DRAWINGS

FIG. 1 is a cross-sectional exploded view of a mechanical feedthrough apparatus in accordance with one embodiment of the present invention.

FIG. 2 is a cross-sectional assembly view of the mechanical feedthrough apparatus in accordance with one embodiment of the present invention.

### DETAILED DESCRIPTION OF THE INVENTION

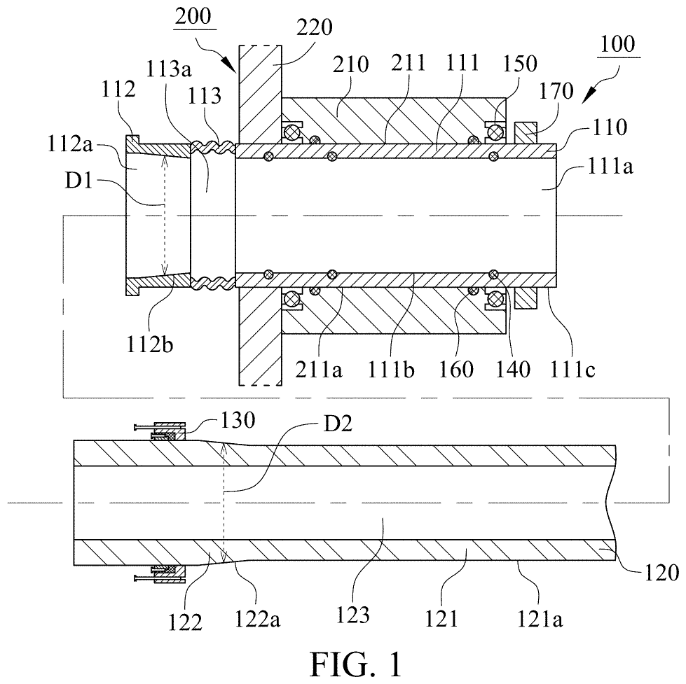

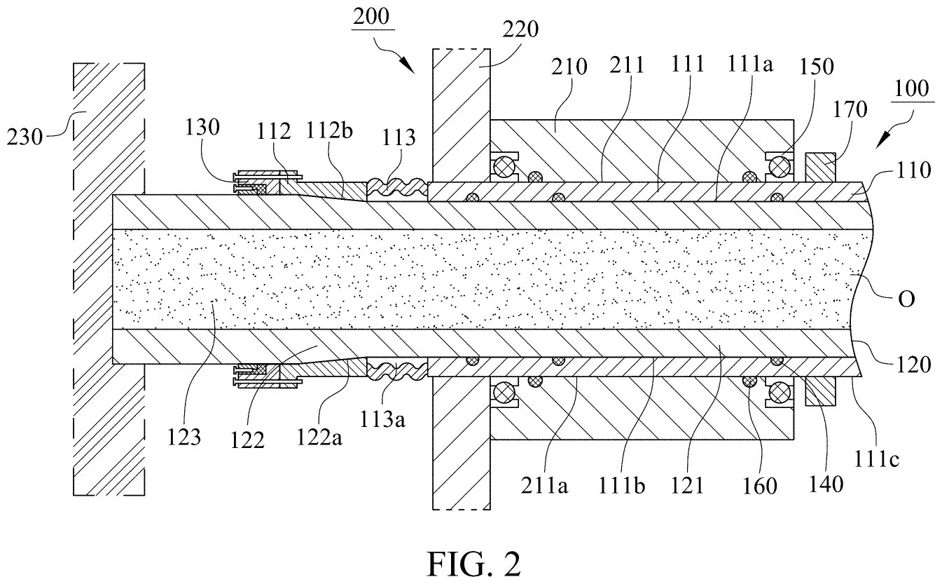

With reference to FIGS. 1 and 2, a mechanical feedthrough apparatus 100 of the present invention is designed to be mounted on a pivot base 210 of a vacuum apparatus 200. The vacuum apparatus 200 is, but not limited to, a vacuum sputtering apparatus and the pivot base 210 is placed in a chamber 220 of the vacuum apparatus 200.

With reference to FIGS. 1 and 2, the mechanical feedthrough apparatus 100 includes a first axial tube 110 and a second axial tube 120. One end of the second axial tube 120 is connected to a stage 230 of the vacuum apparatus 200, which is located in the chamber 220 and provided to carry a workpiece (not shown). In this embodiment, the mechanical feedthrough apparatus 100 is used to preheat the stage 230.

With reference to FIGS. 1 and 2, the first axial tube 110 includes a pivot segment 111 and a joint segment 112, and preferably, further includes an expansion segment 113 located between the pivot segment 111 and the joint segment 112. Both ends of the expansion segment 113 are connected to the pivot segment 111 and the joint segment 112 respectively by welding. The expansion segment 113 may be a bellow tube able to expand between the pivot segment 111 and the join segment 112. The first axial tube 110 is pivotally connected to a pivot opening 211 of the pivot base 210 via the pivot segment 111. In this embodiment, there is at least one bearing 150 disposed between an internal surface 211a of the pivot opening 211 and an external surface 111c of the pivot segment 111 so that the first axial tube 110 is rotatable. Preferably, at least one sealing ring 160 may be disposed between the internal surface 211a of the pivot opening 211 and the external surface 111c of the pivot segment 111.

With reference to FIGS. 1 and 2, the pivot segment 111I has a first joint opening 111a, the joint segment 112 has a second joint opening 112a and the expansion segment 113 has a through opening 113a. The first joint opening 111a communicates with the second joint opening 112a with the help of the through opening 113a. There is an internal cone surface 112b in the second joint opening 112a, and the second joint opening 112a in this embodiment has an internal diameter D1 gradually increased away from the pivot segment 111 so as to form the internal cone surface 112b.

With reference to FIGS. 1 and 2, the second axial tube 120 includes a first joint segment 121 and a second joint segment 122, the first joint segment 121 is inserted in the first joint opening 111a and the second joint segment 122 is inserted in the second joint opening 112a. At least one sealing ring 140 may be preferably disposed between an internal surface 111b of the first joint opening 111a and an external surface 121a of the first pivot segment 121. A delivery passage 123 in the second axial tube 120 is designed for the accommodation of a fluid O which is, but not limited to, heated kerosene.

With reference to FIGS. 1 and 2, the second joint segment 122 has an external cone surface 122a, and an external diameter D2 of the second joint segment 122 increases away from the first joint segment 121 gradually in this embodiment so that the external cone surface 122a is formed on the second joint segment 122. Referring to FIG. 2, the external cone surface 122a of the second axial tube 120 contacts with the internal cone surface 112b of the first axial tube 110 when the second axial tube 120 is inserted into the first axial tube 110. And preferably, the internal cone surface 112b and the external cone surface 122a have substantially identical taper angles, as a result, the external cone surface 122a can tightly contact the internal cone surface 112b to improve the air-tightness between the first axial tube 110 and the second axial tube 120.

With reference to FIGS. 1 and 2, the mechanical feedthrough apparatus 100 preferably further includes a fixer 130 used to integrate the first axial tube 110 and the second axial tube 120. In this embodiment, the fixer 130 is a power lock, which is mounted on the second axial tube 120 and then integrates the first axial tube 110 and the second axial tube 120 after inserting the second axial tube 120 into the first axial tube 110.

With reference to FIGS. 1 and 2, the mechanical feedthrough apparatus 100 further includes a tube bundle 170 set on the first axial tube 110 and to located outside of the pivot base 210. When the second axial tube 120 is inserted into the first axial tube 110, the tube bundle 170 is provided to tightly bind the first axial tube 110 and the second axial tube 120 for improvement of the integration strength and air-tightness between the first axial tube 110 and the second axial tube 120.

With reference to FIG. 2, the fluid O is delivered to the delivery passage 123 by a delivery apparatus such as pump (not shown) to preheat the stage 230 of the vacuum apparatus 200. In this embodiment, a power plant such as drive motor (not shown) is provided to actuate the first axial tube 110 in rotation so as to rotate the second axial tube 120 and the stage 230 together for sputtering.

With reference to FIG. 2, the connection contact of the second axial tube 120 and the first axial tube 110 through the external cone surface 122a and the internal cone surface 112b can enlarge the contact area of which, and the heated fluid O delivered to the delivery passage 123 can make the second axial tube 120 expand such that the external cone surface 122a can be tightly attached to the internal cone surface 112b to increase the air-tightness between the second axial tube 120 and the first axial tube 110. Additionally, while the second axial tube 120 is heated to expand axially, the first axial tube 110 can expand axially together with the second axial tube 120 because of the expansion segment 113, for this reason, the reduction of the air-tightness between the first axial tube 110 and the second axial tube 120 caused by the expansion of the second axial tube 120 is preventable.

While this invention has been particularly illustrated and described in detail with respect to the preferred embodiments thereof, it will be clearly understood by those skilled in the art that is not limited to the specific features to shown and described and various modified and changed in form and details may be made without departing from the spirit and scope of this invention.

What is claimed is:

1. A mechanical feedthrough apparatus provided to be mounted on a pivot base of a vacuum apparatus, comprising:
a first axial tube including a pivot segment and a joint segment, the pivot segment is pivotally connected to a pivot opening of the pivot base and has a first joint opening, the joint segment has a second joint opening communicating with the first joint opening, wherein there is an internal cone surface in the second joint opening; and
a second axial tube including a first joint segment and a second joint segment, the first joint segment is inserted in the first joint opening and the second joint segment is inserted in the second joint opening, wherein there is an external cone surface on the second joint segment and the second axial tube is contacted via the external cone surface with the internal cone surface.

2. The mechanical feedthrough apparatus in accordance with claim 1, wherein the internal and external cone surfaces have substantially identical taper angles.

3. The mechanical feedthrough apparatus in accordance with claim 1, wherein the second joint opening has an internal diameter gradually increased away from the pivot segment so as to form the internal cone surface.

4. The mechanical feedthrough apparatus in accordance with claim 2, wherein the second joint opening has an internal diameter gradually increased away from the pivot segment so as to form the internal cone surface.

5. The mechanical feedthrough apparatus in accordance with claim 1, wherein the second joint segment has an external diameter gradually increased away from the first joint segment so as to form the external cone surface.

6. The mechanical feedthrough apparatus in accordance with claim 2, wherein the second joint segment has an external diameter gradually increased away from the first joint segment so as to form the external cone surface.

7. The mechanical feedthrough apparatus in accordance with claim 1, wherein the first axial tube further includes an expansion segment located between the pivot segment and the joint segment, the expansion segment has a through opening, the first joint opening communicates with the second joint opening via the through opening, and the expansion segment is able to expand between the pivot segment and the joint segment.

8. The mechanical feedthrough apparatus in accordance with claim 1 further comprising a fixer, wherein the first and second axial tubes are integrated with each other by the fixer.

9. The mechanical feedthrough apparatus in accordance with claim 8, wherein the fixer is a power lock.

10. The mechanical feedthrough apparatus in accordance with claim 1, wherein there is at least one sealing ring disposed between an internal surface of the first joint opening and an external surface of the first joint segment.

11. The mechanical feedthrough apparatus in accordance with claim 1, wherein there is at least one bearing disposed between an internal surface of the pivot opening and an external surface of the pivot segment.

12. The mechanical feedthrough apparatus in accordance with claim 1 further comprising a tube bundle disposed on the first axial tube, wherein the tube bundle is provided to bind the first and second axial tubes tightly.
